(19) United States
(12) Patent Application Publication
(10) Pub. No.: US 2007/0031997 A1
(43) Pub. Date: Feb. 8, 2007

(54) Jig and vacuum equipment for surface adhesion and adhesion method using the vacuum operative adhesion

(75) Inventors: Byoung-hun Lee, Hwaseong-si (KR); Ho-min Kang, Suwon-si (KR); Hoon-kee Min, Seoul (KR); Jeong-ho Hwang, Suwon-si (KR); Sung-min Kim, Yongin-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/499,370

(22) Filed: Aug. 4, 2006

(30) Foreign Application Priority Data
Aug. 4, 2005 (KR) 10-2005-0071427

(51) Int. Cl. H01L 21/00

(52) U.S. Cl. 438/123

(57) ABSTRACT

Provided is a jig which can be used in a process of adhering a adhering object to a to-be adhered object in a vacuum atmosphere, and vacuum equipment for use in the adhering process. The jig includes a first frame and a second frame which together define a chamber for receiving the first and second objects. The first frame includes a seating portion having a plurality of seating pockets, and an actuator disposed below each of the seating pockets, the actuator being movable with respect to the seating pockets. A first elastic member is disposed in the jig below the actuator. The first elastic member being positioned such that it can contact and move the actuator in response to a change of pressure in the jig chamber. The second frame includes a second elastic member which is positioned adjacent to each of the seating pockets. The second elastic member being movable to the change of pressure in the jig chamber.

This application claims priority from Korean Patent Application No. 10-2005-0071427 filed on Aug. 4, 2005 in the Korean Intellectual Property Office, the disclosure of which is incorporated herein by reference in its entirety.

### BACKGROUND OF THE INVENTION

1. Field of the Invention

The present invention relates to a jig and vacuum equipment for adhering objects together and an adhesion method using the vacuum equipment, and more particularly, to a jig for adhering objects in a vacuum atmosphere, vacuum equipment for surface adhesion and an adhesion method using the vacuum equipment.

2. Description of the Related Art

In general, a liquid crystal panel includes a first substrate having a thin film transistor (TFT) array, a second substrate having a color filter layer, with the first and second substrates connected to each other and with a liquid crystal interposed there between the first and second substrates. Fabrication of a liquid crystal display is completed by attaching a driving IC, and other functional elements to the liquid crystal panel. The thus-completed liquid crystal display can be used in various devices that require image realization, for example, in portable display devices, such as mobile phones, notebook computers, and personal digital assistants (PDAs).

The liquid crystal panel is seated in a predetermined frame structure and encapsulated in a casing having a window through which an image display portion is revealed. In order to protect the image display portion of the liquid crystal panel, a protective window made of glass or a plastic material is formed and spaced a predetermined distance from the liquid crystal panel. However, the protective window is typically bulky and heavy and is easily damaged by external shocks. To eliminate such disadvantages associated with the use of the protective window, an LCD having a screen display portion adhered to a liquid crystal panel interposing a transparent adhesive layer having a shock-absorbing function has been developed, the transparent film being made of polymethylmetaacrylate (PMMA), polyethyleneterephtalate (PET), or polycarbonate (PC).

However, in the prior art adhesion of the transparent film having the adhesive layer to the liquid crystal panel is not easily performed, and often bubbles are generated between the adhesive layer and the liquid crystal panel, consequently resulting in a defective LCD.

### SUMMARY OF THE INVENTION

The present invention provides a jig for use in a process of adhering a transparent film to a liquid crystal panel, which suppresses the generation of bubbles between the film and the liquid crystal panel.

The present invention also provides a jig for surface adhesion, which performs surface adhesion without causing damage to a film and a panel.

The present invention also provides vacuum equipment for surface adhesion including the jig.

The present invention also provides an adhesion method for adhering an adhering object to a to-be-adhered object using vacuum equipment.

According to an aspect of the present invention,

there is provided a jig for surface adhesion, the jig including a first frame comprising a plurality of seating pockets, a plurality of actuators, each actuator having an associated seating pocket, and a first flexible membrane positioned below the actuators; and a second frame adapted to cooperate with the first frame, the second frame including a second flexible membrane.

According to another aspect of the present invention, there is provided vacuum equipment including a jig having a first frame comprising a plurality of seating pockets, a plurality of actuators, each actuator having an associated seating pocket, and a first flexible membrane positioned below the actuators and a second frame adapted to cooperate with the first frame, the second frame including a second flexible membrane;

According to still another aspect of the present invention, there is provided an adhesion method comprising placing the adhering object and the to-be-adhered object on an actuator and a seating pocket, respectively, of a jig, moving a second frame of the jig into contact with a first frame of the jig; placing the jig in a chamber, evacuating the jig and the chamber, respectively; and releasing a vacuum of the chamber

### BRIEF DESCRIPTION OF THE DRAWINGS

The above and other features and advantages of the present invention will become more apparent by describing in detail exemplary embodiments thereof with reference to the attached drawings in which:

FIGS. 1 and 2 provide a perspective view and a cross-sectional view respectively, of a jig for surface adhesion according to an embodiment of the present invention.

FIG. 3 is another perspective view of a first frame of the jig shown in FIG. 1;

FIGS. 4A and 4B are plan views illustrating modified examples of a second frame for use with the jig shown in FIG. 1;

FIG. 5 is a perspective view of a jig for surface adhesion according to another embodiment of the present invention;

FIG. 6 is a perspective view of a shock-absorbing member included in a jig for surface adhesion according to an embodiment of the present invention;

FIG. 7 is a perspective view of vacuum equipment including a jig for surface adhesion according to an embodiment of the present invention;

FIG. 8 is an exploded perspective view of a to-be-adhered object adhered using an adhesion method according to an embodiment of the present invention;

FIG. 9 is a perspective view of an adhering object adhered using the adhesion method shown in FIG. 8;

FIG. 10 is a flowchart for explaining the adhesion method shown in FIG. 10;

FIG. 11 is a cross-sectional view illustrating that the adhering object and the to-be-adhered object are mounted on a jig for surface adhesion according to an embodiment of the present invention;

FIG. 12 is a perspective view in which a jig according to an embodiment of the present invention is received in a chamber; and

FIG. 13 is a cross-sectional view of the jig for surface adhesion after the application of vacuum which results in an adhering object and a to-be-adhered object being moved into contact.

### DETAILED DESCRIPTION OF THE INVENTION

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. The same numerals refer to same elements throughout the specification. In the attached figures, the thickness of layers and regions is exaggerated for clarity.

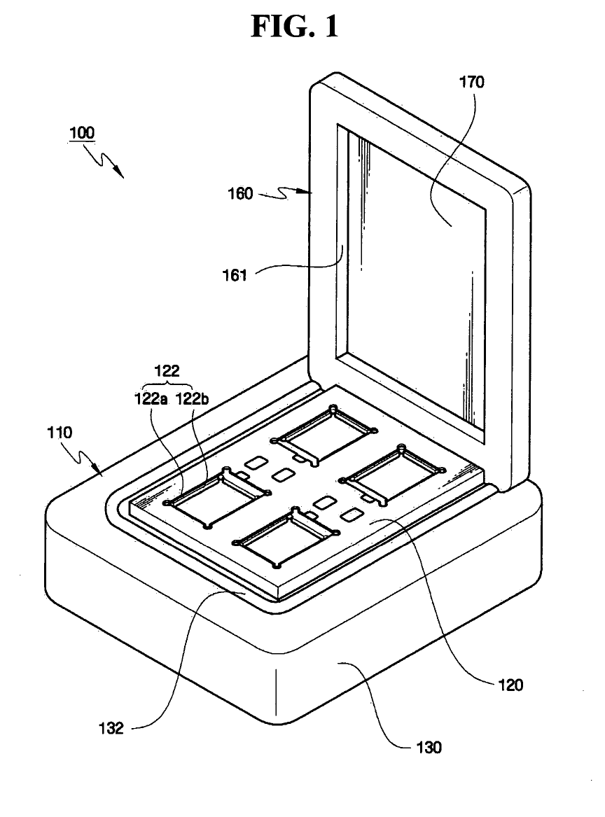

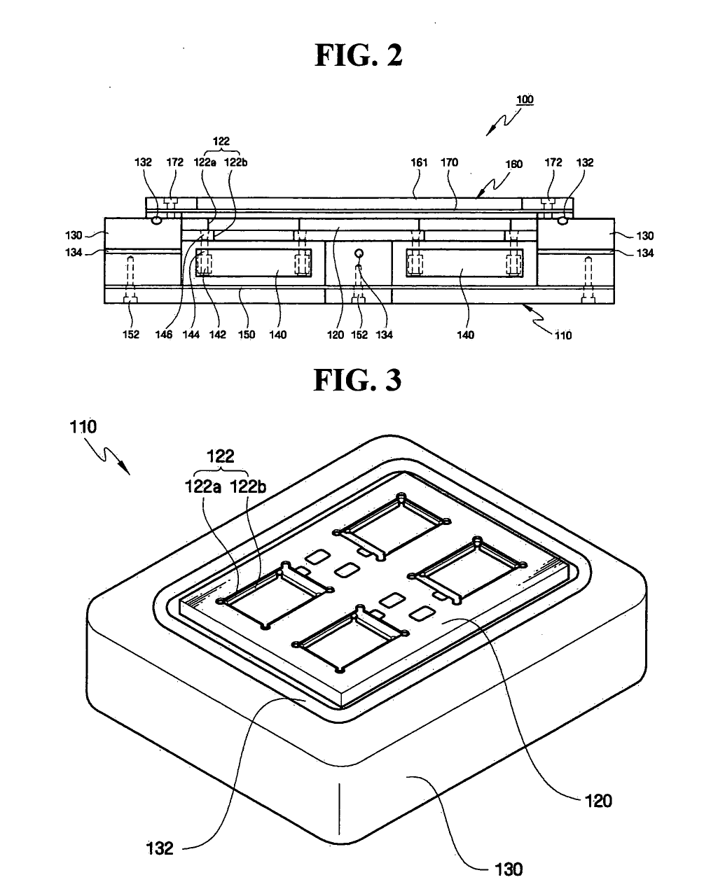

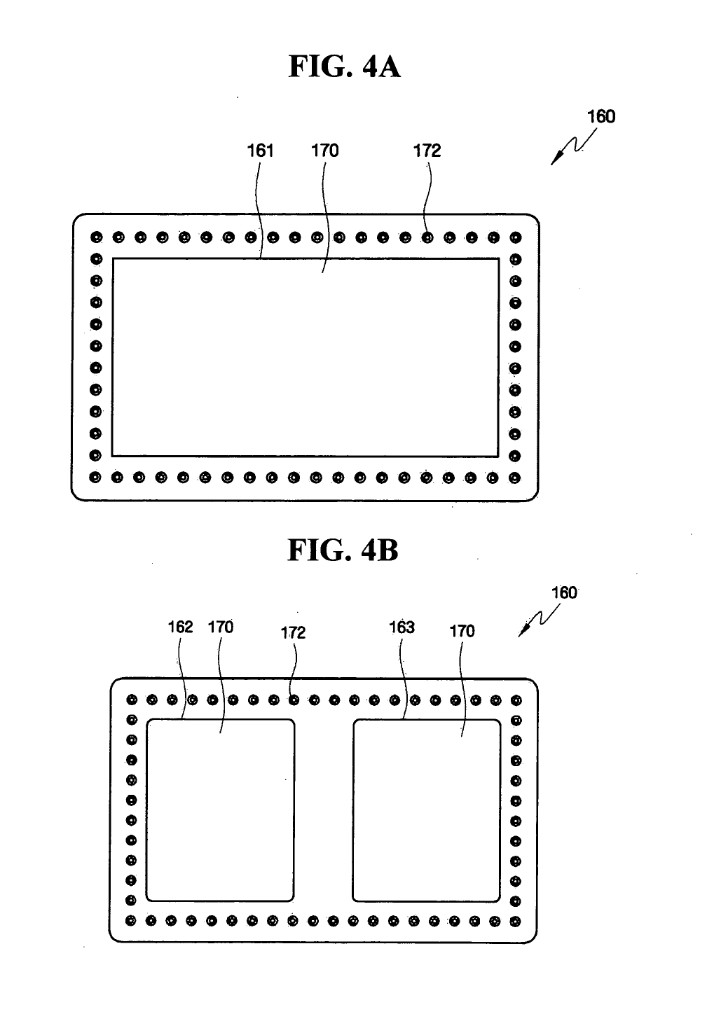

Hereinafter, a jig according to an embodiment of the present invention is described with reference to FIGS. 1 through 4B. FIGS. 1 and 2 are a perspective view and a cross-sectional view respectively of a jig according to an embodiment of the present invention. FIG. 3 is a perspective view of a first frame of the jig shown in FIG. 1, and FIGS. 4A and 4B are plan views illustrating modified examples of a second frame 160 for use with the first frame shown in FIG. 1.

The jig 100 includes a first frame 110 and a second frame 160.

Referring to FIGS. 1 through 3, the first frame 110 includes a seating portion 120 in which a to-be-adhered object will be disposed, an actuator 140 on which the adhering object will be disposed, and a first flexible membrane 150 which moves the actuator 140 in an upward direction. The first flexible membrane 150 may be made of, for example, silicone-based rubber, synthetic resin.

The seating portion 120 is placed on the top surface of the first frame 110 and includes a plurality of seating pockets 122 for mounting an object. The seating pockets 122 may have a variety of shapes depending on the shape of the object, such as rectangular, circular, or oval shapes. Preferably, the seating pockets 122 have a rectangular shape. To facilitate seating of the object, each of the seating pockets 122 may consist of an upper pocket 122a having a first circumference and a lower pocket 122b having a second circumference, the upper pocket 122a and the lower pocket 122b being connected to each other. The central portions of the pockets overlap each other, the first circumference being greater than the second circumference. As illustrated, the upper pocket 122a has a greater circumference than the lower pocket 122b so that each of the seating pockets 122 has a stepped configuration. Seating portion 120 may be made of a metal such as stainless steel, aluminum or iron processed with anti-rust treatment which can withstand pressure.

A supporting portion 130 is formed along an outer circumference of the seating portion 120. The supporting portion 130 supports the seating portion 120 and provides for a space below the seating portion 120. A sealant 132, which may be composed of silicon rubber, is placed in a groove on the supporting portion 130 and is positioned outwardly from the outer circumference of the seating portion 120 by a predetermined distance so that the second frame 160, which will be described later, can be close to the first frame 110 and form a sealed space. In addition, at least one aperture 134 through which air can enter in an internal space formed by the seating portion 120 and the supporting portion 130 (hereinafter, referred to as an internal space) be discharged may be formed in the supporting portion 130. In addition, a vacuum connector (not shown) that can be connected to an external vacuum unit for evacuating the internal space may be formed in the supporting portion 130. In addition, a sensor connector (not shown) for detecting a state of the internal space, such as a degree of vacuum or a degree of pressure, may be formed in the supporting portion 130. In this case, at least one outlet 134, the vacuum connector, and the sensor connector should be formed at a location between flexible membrane 150 and flexible membrane 170. The supporting portion 130 supports the seating portion 120 and is made of, for example, stainless steel that can withstand pressure, iron processed with anti-rust treatment, e.g., chrome-plating, or a metal such as aluminum.

The actuators 140 on which the object is supported are positioned in the spaces formed by the seating portion 120 and the supporting portion 130. Each actuator 140 allows the adhering object to be closer to or separated from the object. In order to facilitate mounting of the adhering object, a surface of the actuator 140 on which the adhering object is mounted should be larger than a surface of the adhering object. Hereinafter, the surface will be referred to as a top surface. Meanwhile, one or more passages that extend from a non-adhesive region corresponding to a region other than a region where the adhering object is placed to a region facing the region (hereinafter, referred to as a bottom surface) may be formed on the top surface of the actuator 140. In addition, a guide 144 having a bearing 142 is formed in the passages. One end of the guide 144 is fixed to the seating portion 120 using a fixing unit 146 such as a screw, and the actuator 140 can move in upward and downward directions along the guide 144. Actuators 140 may be made of a variety of materials including a thermally conductive material, such as aluminum, that can transfer heat generated from a heating unit that will be described later to the adhering object.

The first flexible membrane 150 for applying a moving force that makes the actuator 140 move in a longitudinal direction is disposed below the actuator 140. The first flexible membrane 150, which is fixed on the supporting portion 130 by fixing means 152 such as a screw, elongates or shrinks responsive to the change of pressure, moves the actuator 140 disposed on the first flexible membrane 150 in a longitudinal direction along the guide 144 to make the adhering object approach to the to-be-adhered object. The first flexible membrane 150 may be made of materials having various properties of at least heat resistance, elasticity, resilience, and so on. For example, silicone rubber may be suitably used as the first flexible membrane 150. However, the first flexible membrane 150 is not particularly limited to the illustrated example and any synthetic resin may be used as long as it has heat resistance, elasticity or resilience. Here, a thickness of the first flexible membrane 150 may be in a range of 1-4 mm, for example, and can be appropriately changed as a function of a weight of the actuator 140 and a distance between the to-be-adhered object and the adhering object.

Next, the second frame 160 of jig 100 will be described. Referring to FIGS. 1, 2, 4A, and 4B, the second frame 160 is connected with the first frame 110 to form a vacuum space. The second frame 160 serves as a cover for the first frame 110. The second frame 160 can be connected to the second frame 160 using a connecting unit (not shown), such as a hinge, so as to be close to or separated from the first frame 110.

Referring to FIG. 4A, the second frame 160 may be shaped such that it surrounds all of the seating pockets 122 of the seating portion 120 of the first frame 110. That is, the second frame 160 may be shaped such that it includes aperture 161 and a second flexible membrane 170 covering the aperture 161. Alternatively, as shown in FIG. 4B, the second frame 160 may be shaped such that it divides the seating pockets 122 formed in the seating portion 120 of the first frame 110 into two parts, that is, into two apertures 162 and 163, and that second flexible membrane 170 covers the apertures 162 and 163. In this case, the second flexible membrane 170 can be fixed in the second frame 160 using a fastener 172, such as a screw. In this specification, the shape of the second frame 160 has been specifically illustrated as described above, which is, however, illustrative only, and the second frame 160 can have various shapes according to uses of the jig 100.

The second frame 160 may be made of stainless steel that can withstand pressure, iron processed with anti-rust treatment, e.g., chrome-plating, or a metal such as aluminum. In addition, the second flexible membrane 170 may be made of materials having various properties of at least heat resistance, elasticity, resilience, and so on. For example, silicone rubber may be suitably used for the second flexible membrane 170. Here, a thickness of the second flexible membrane may be in a range of 1-4 mm, for example, and can be appropriately changed as a function of uses of the jig 100.

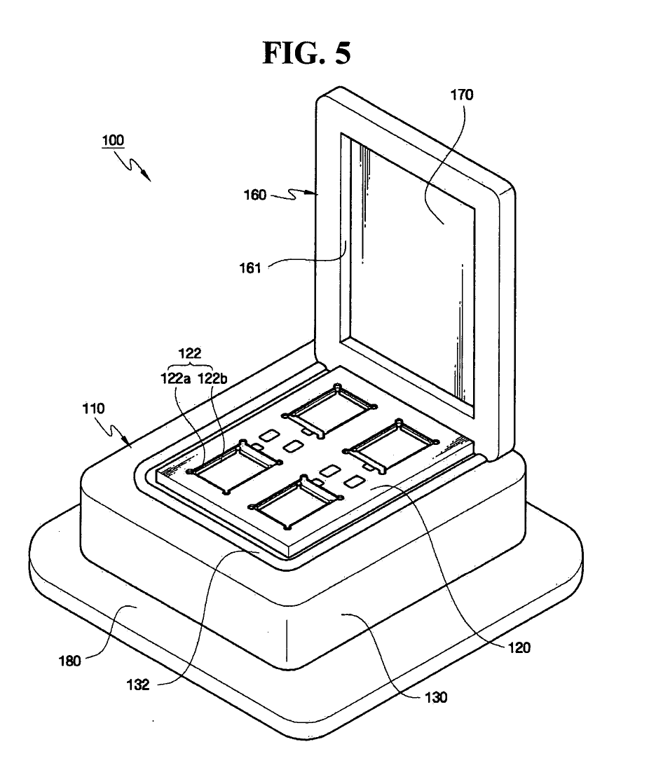

Referring to FIG. 5, in order to improve adhesion of the adhering object with respect to the to-be-adhered object, the jig 100 having the first frame 110 and the second frame 160 according to an embodiment of the present invention may further include a heating unit 180 disposed below the second frame 160. In an exemplary embodiment, the heating unit 180 is a hot plate. Heating unit 180 may include one or more passages for circulating a heating fluid such as oil or vapor or may utilize electronic induction heating.

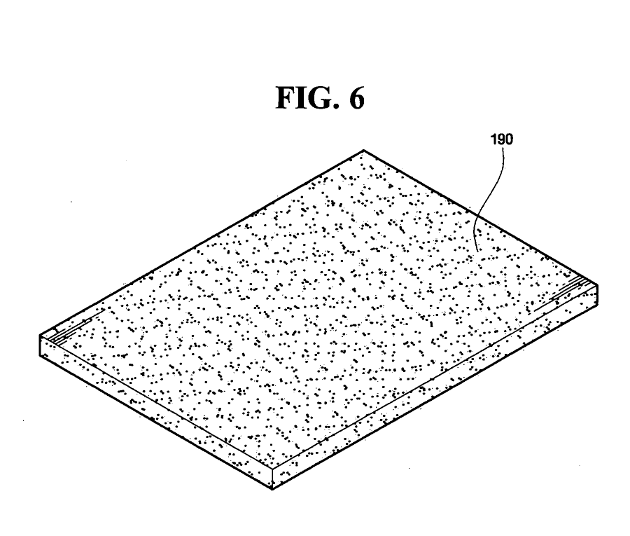

Referring to FIG. 6, the jig 100 may further include a shock-absorbing member 190 disposed on a top surface of the actuator 140. The shock-absorbing member 190 prevents pressure applied when the adhering object and the to-be-adhered object are adhered to each other from being concentrated on a predetermined portion. Thus, when the pressure is applied to the adhering object and the to-be-adhered object, the shock-absorbing member 190 can maintain the adhering object and the to-be-adhered object to be parallel to the top surface of the actuator 140 and perfect surface adhesion can be achieved almost concurrently. The shock-absorbing member 190 is not particularly limited in its material used but may be made of an elastic material that enables uniform distribution of pressure. A variety of materials may be used according to a degree of pressurization and the type of the adhering object and the to-be-adhered object.

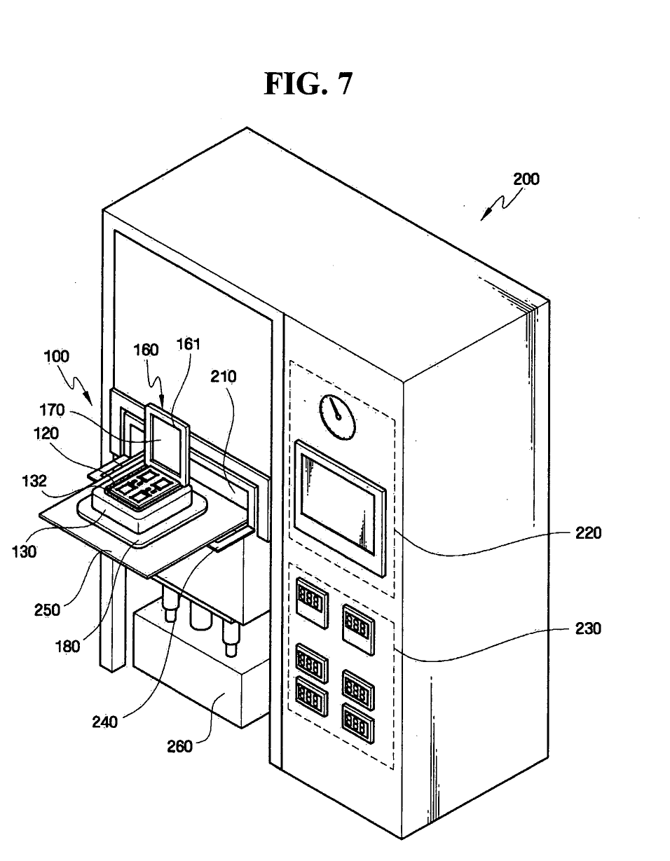

Vacuum equipment for use with a jig according to an embodiment of the present invention will now be described with reference to FIG. 7. FIG. 7 is a perspective view of vacuum equipment including a jig for surface adhesion according to an embodiment of the present invention.

Referring to FIG. 7, vacuum equipment 200 includes a jig 100, a chamber 210 in which the jig 100 is received, a vacuum unit that is connected to the jig 100 and the chamber 210, respectively, a display unit 220 that monitors a degree of vacuum and a degree of pressurization of the jig 100 and the chamber 210, and a controller 230 that controls the display unit 220. The jig 100 shown in the current embodiment is the same as the jig shown in the previous embodiment and a detailed description thereof is not required.

The chamber 210 of the vacuum equipment in which the jig 100 is received has a sufficient internal space which can receive the jig 100 and has a door 240 that allows the jig 100 to receive and to be discharged. Door 240 may include a transparent window to allow a viewer to observe the inside of the chamber 210 from the outside even when it is closed. In addition, a sealant (not shown) may be positioned on the door 240 or a main body of the chamber 210 that is in contact with the door 240 to keep a vacuum state when the inside of the chamber 210 is made vacuous. In addition, when the jig 100 is received in the chamber 210, a supporting board 250 is provided to support jig 100 as it is moved into or out of the chamber 210 in a sliding manner.

In addition, a vacuum tube (not shown) is connected between vacuum unit 260 and the inside of the chamber 210 to apply a vacuum; and a sensor (not shown) is connected to chamber 210 for detecting a degree of vacuum and a degree of pressurization of each of the jig 100 and the inside of the chamber 210. In addition, when a heating unit is included in the jig 100, a power supply unit (not shown) for supplying power to the heating unit may be included in the chamber 210.

The display unit 220 of the vacuum equipment 200 displays a degree of vacuum and a degree of pressurization of the jig 100 and the inside of the chamber 210 detected by the sensor. The degree of vacuum and the degree of pressure of the jig 100 and the inside of the chamber 210 displayed in the display unit 220 is checked, and the controller 230 controls the degree of vacuum and the degree of pressure of the jig 100 and the inside of the chamber 210 to the desired levels.

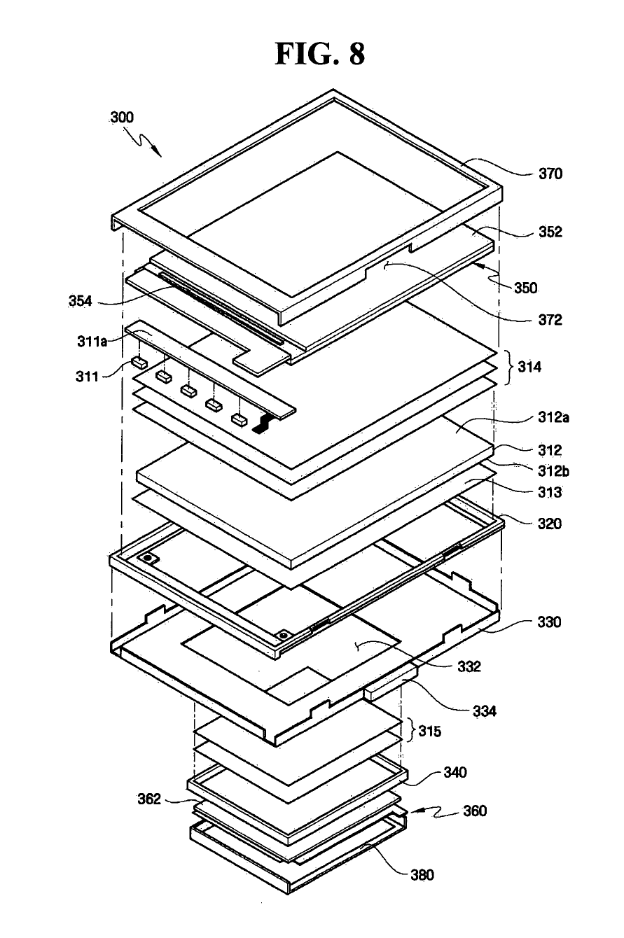

An adhesion method using the vacuum equipment according to an embodiment of the present invention is described below with reference to FIGS. 8 through 13.

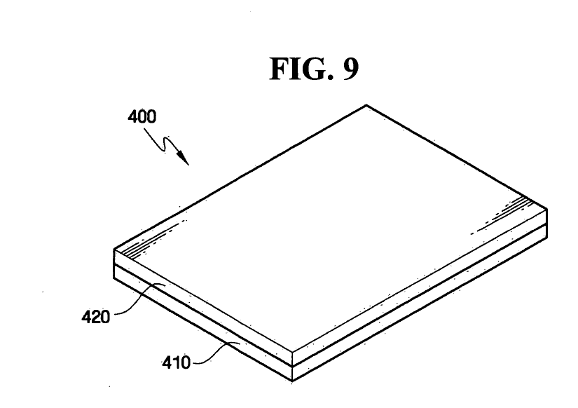

First, the to-be-adhered object using the adhesion method according to an embodiment of the present invention and the adhering object will be described with reference to FIGS. 8 and 9. FIG. 8 is an exploded perspective view of a to-be-adhered object adhered using an adhesion method according to an embodiment of the present invention, and FIG. 9 is a perspective view of an adhering object adhered using the adhesion method shown in FIG. 8.

Referring to FIG. 8, the to-be-adhered object 300 may be implemented as a liquid crystal panel assembly, for example. The liquid crystal panel assembly may be a bidirectional liquid crystal panel assembly that displays an image in either direction. In this case, the thickness of a liquid crystal panel assembly becomes an important issue. The liquid crystal panel assembly includes a backlight unit, first through third receiving containers, and first and second display units.

First, the backlight unit includes a light source 311, a light guide panel 312, a light amount controlling sheet 313, and first and second optical sheets 314 and 315. The light source 311 may be placed at one side of the light guide panel 312 and a light emitting diode (LED), for example. Alternatively, the light source 311 may be a cold cathode fluorescent lamp (CCFL). For example, when the light source 311 includes a plurality of LEDs, the LEDs are fixed on a flexible printed circuit board (FPCB) 311a in one line and generate light in response to a driving voltage applied through the FPCB 311a.

The light guide panel 312 changes the path of incident light from the light source 311 to emit light in both directions, that is, onto first and second emission sides 312a and 312b, respectively. The light amount controlling sheet 313 reflects a portion of incident light through the second emission side 312b and transmits and diffuses some of the remaining portion of the incident light.

The first optical sheets 314 are used to improve the brightness uniformity and front brightness of light emitted in a first direction through the first emission side 312a.

The second optical sheets 315 are used to improve the brightness characteristic of light transmitting the light amount controlling sheet 313 of light emitted in a second direction through the second emission side 312b. The second optical sheets 315 may be formed to have substantially the same surface area to that of the second emission side 312b and the light amount controlling sheet 313 but can be changed in various ways according to the size and position that a user wants. At this time, the second optical sheets 315 may have a size corresponding to the size of a second display unit 360 that displays an image using light passing through the second optical sheets 315 and will be described later.

Receiving positions of the light source 311 and the light guide panel 312 are guided by a first receiving container 320 having a rectangular frame shape. A second receiving container 330 is combined with the first receiving container 320 and forms a receiving space. The light amount controlling sheet 313, the light source 311, and the light guide panel 312 are sequentially mounted on the receiving space. An aperture 332 corresponding to the size of the second optical sheets 315 is formed in the second receiving container 330, and light transmitting the light amount controlling sheet 313 proceeds in a direction of the second optical sheets 315 through the aperture 332. In addition, a stopper 334 is formed on at least a pair of sides of the second receiving container 330 that face each other so that the liquid crystal panel assembly 300 can be easily mounted on the seating pockets 122 of the jig 100. The stopper 334 will be described later. A third receiving container 340 is combined with a position corresponding to the aperture 332 from the rear side of the second receiving container 330. The third receiving container 340 fixes the second optical sheets 315.

The first display unit 350 is mounted on the first receiving container 320 from the upper portion of the first optical sheets 314. The first display unit 350 includes a first liquid crystal panel 352 for displaying a first image. The first liquid crystal panel 352 displays a first image using light that is emitted from the first emission side 312a of the light guide panel 312 and transmits the first optical sheets 314. The first display unit 350 further includes a first driving chip 354 for driving the first liquid crystal panel 352. The first driving chip 354 can be directly mounted on the first liquid crystal panel 352. The second display unit 360 is mounted on the third receiving container 340.

The second display unit 360 includes a second liquid crystal display panel 362 for displaying a second image and a second driving chip (not shown). The second liquid crystal display panel 362 displays a second image using light in a second direction that is emitted from the second emission side 312b of the liquid guide panel 312 and transmits the light amount controlling sheet 313 and the second optical sheets 315. At this time, the second image may be the same as or different from the first image.

The first liquid crystal display panel 352 and the second liquid crystal display panel 362 may be formed to the same size or a different size according to a user's need. In the present specification, the second liquid crystal display panel 362 has a smaller size than the first liquid crystal display panel 352.

In addition, the bidirectional liquid crystal panel assembly 300 includes a first chassis 370 combined with the first receiving container 320 so as to fix the first liquid crystal display panel 350, and a second chassis 380 combined with the third receiving container 340 so as to fix the second liquid crystal display panel 362. The first and second chassis 370 and 380 prevent the deviation of the first and second liquid crystal display panels 352 and 362 and simultaneously protect them from external shocks. A groove 372 having a predetermined depth is formed in a position of the first chassis 370 that corresponds to a portion where the stopper 334 of the second receiving container 330 is formed.

Referring to FIG. 9, an adhering object 400 may be a transparent film 410 having an adhesive layer 420 formed on one side. For example, the transparent film 410 is used to protect the first liquid crystal display panel 352 of the first display unit 350. The transparent film 410 should be scratch resistant and have chemical resistance and transmittance at least 60%, preferably more than 90%, for example, so that an image displayed on the first liquid crystal display panel 352 can be observed from the outside. Thus, the transparent film 410 may be made of polymethylmetaacrylate (PMMA), polyethyleneterephtalate (PET), polycarbonate (PC), or others. In this case, a thickness of the transparent film 410 is preferably in a range of about 2 to about 8 mm, but is not limited to the specified range.

The adhesive layer 420 formed on one side of the transparent film 410 is used for adhesion with the to-be-adhered object 300, that is, the liquid crystal panel assembly. The adhesive layer 420 serves to absorb shocks applied to the liquid crystal panel assembly as the to-be-adhered object 300. The adhesive layer 420 should have excellent adhesion and high light transmittance, for example, at least 60%, preferably more than 90%, so that an image displayed on the first liquid crystal display panel 352 can be observed from the outside. Adhesive layer 420 may include silicon resin or acryl resin. Here, a thickness of the adhesive layer 420 is preferably in a range of about 2 to about 5 mm, but is not limited to the specified range.

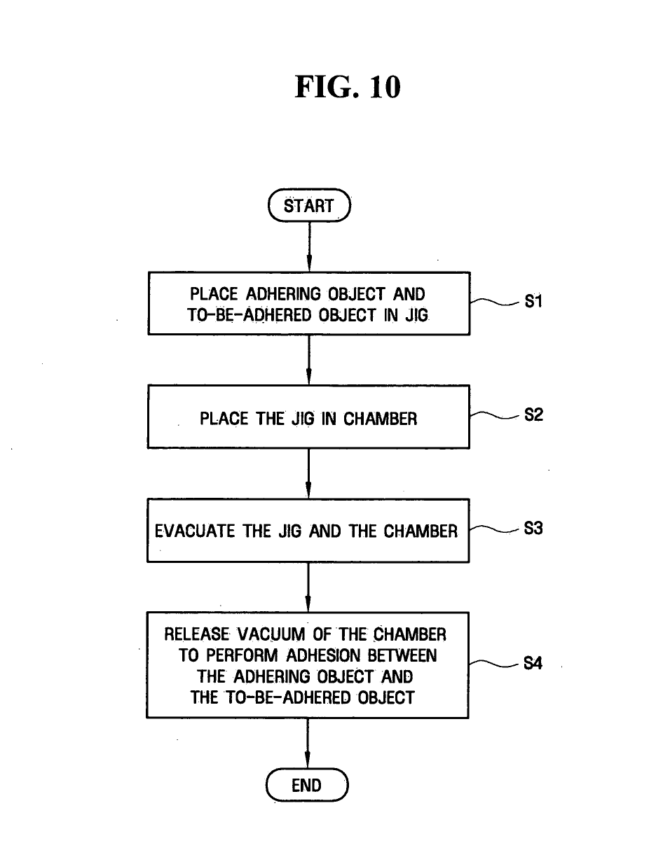

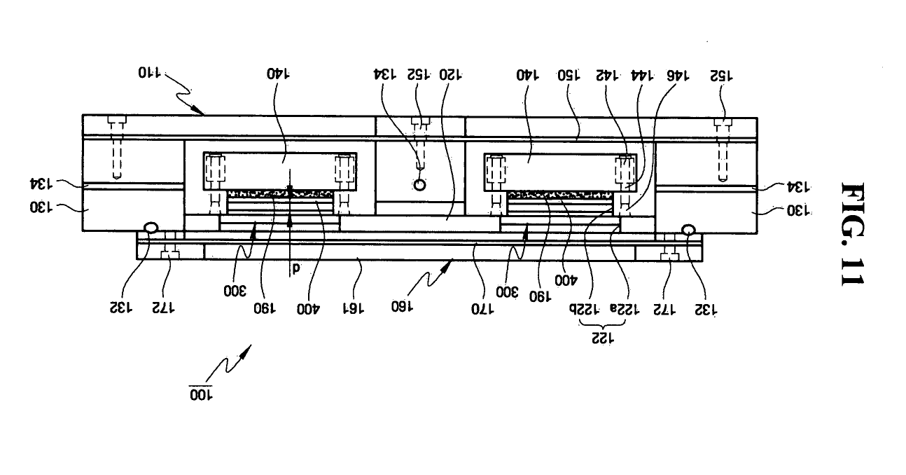

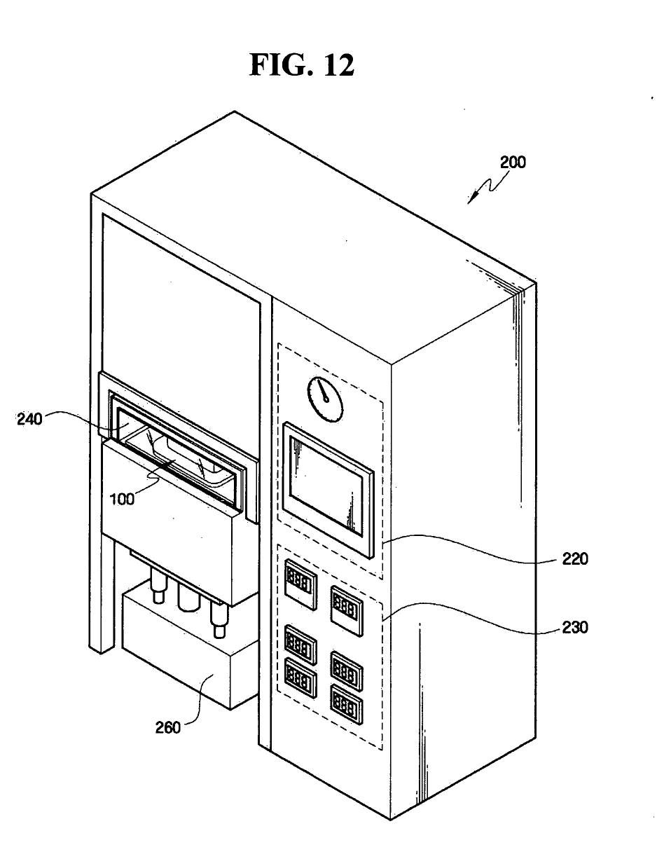

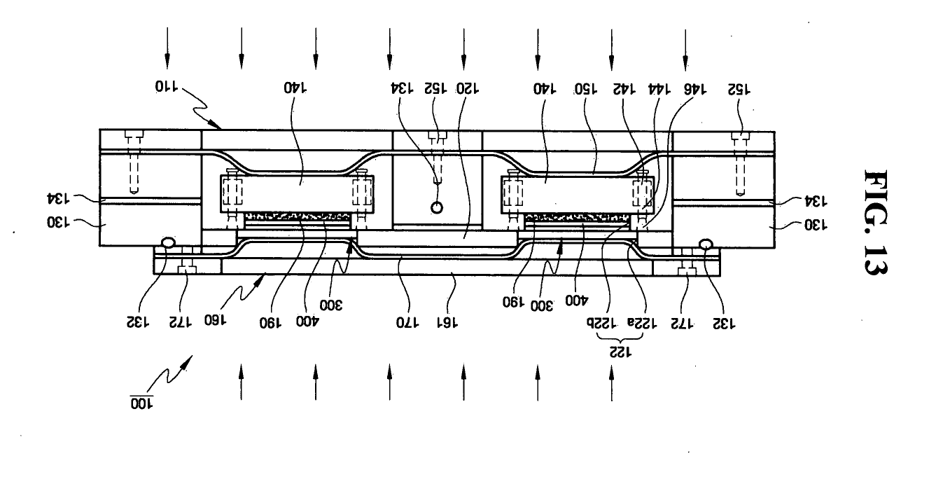

The adhesion method according to an embodiment of the present invention is described below in detail with reference to FIGS. 10 through 13. FIG. 10 is a flowchart illustrating the adhesion method, and FIG. 11 is a cross-sectional view illustrating that the adhering object and the to-be-adhered object are mounted on a jig for surface adhesion according to an embodiment of the present invention. FIG. 12 is a perspective view in which a jig according to an embodiment of the present invention is received in a chamber, and FIG. 13 is a cross-sectional view of the jig for surface adhesion after the application of a vacuum which results in an adhering object and a to-be-adhered object being moved into contact.

Referring to FIG. 10, the adhering object and the to-be-adhered object are mounted on the jig 100 in operation S1.

More specifically, referring to FIG. 11, while the second frame 160 is separated from the first frame 110 of the jig 100, the shock-absorbing member 190 is mounted on the top surface of the actuator 140 of the first frame 110 and then, the transparent film 410 of the adhering object and the shock-absorbing member 190 come into contact. At this time, since there is no force for moving the actuator 140 upward from the bottom surface of the actuator 140, the actuator 140 is separated from the seating pockets 122 by a predetermined distance d, for example, about 3 mm.

Next, the to-be-adhered object is mounted on the seating pockets 122 of second frame. As described above, each of the seating portions 122 includes an upper pocket 122a having a first circumference and a lower pocket 122a that is connected to the upper pocket 122a and has a second circumference that is smaller than the first circumference. Due to a difference in the circumference between the upper pocket 122a and the lower pocket 122b, a step is formed in the seating pocket 122. Because of the step of the first seating pocket 122, the to-be-adhered object 300, for example, the stopper (334 of FIG. 8) of the second receiving container (330 of FIG. 8) of the liquid crystal panel assembly 300 is locked and placed on the seating pockets 122. Here, since the first liquid crystal panel (352 of FIG. 8) of the liquid crystal panel assembly 300 is exposed toward the adhering object 400 by the lower pocket 122b of the seating pocket 122, the first liquid crystal panel 352 and the lower pocket 122b should have substantially the same shapes. In addition, since the adhering object 400, attached to the first liquid crystal panel 352, serves to the first liquid crystal panel 352, the adhering object 400, the first liquid crystal panel 352 and the lower pocket 122b should have substantially the same shapes.

Subsequently, the second frame 160 is made to approach to the first frame 110 to hermetically seal the jig 100.

Subsequently, the jig 100 is received in the chamber 210 in operation S2, as shown in FIG. 10.

Referring to FIG. 12, the door 240 formed in the chamber 210 of the jig 100 is opened, the jig 100 is received in the chamber 210, and in order to make the inside of the jig 100 vacuous, a vacuum connector (not shown) of the jig 100 and a vacuum tube (not shown) formed in the chamber 210 are connected to each other. In addition, in order to monitor the state of the inside of the jig 100, a sensor connector (not shown) of the jig 100 and a sensor (not shown) formed in the chamber 210 are connected to each other. In addition, in order to supply power to a heating unit (180 of FIG. 5) included in the jig 100, the heating unit is connected to a power supply unit (not shown) inside the chamber 210. Next, the switch 240 is closed.

Subsequently, the jig 100 and the chamber 210 are made vacuous in operation S3, as shown in FIG. 10.

Referring to FIG. 12, the vacuum unit 260 connected to the jig 100 and the chamber 210, e.g., a vacuum pump, is actuated, to make the inside of the jig 100 and the inside of the chamber (210 of FIG. 7) vacuous. A degree of vacuum of the jig 100 and the chamber 210 is monitored while observing the display unit 220 of the vacuum equipment 200, and the controller 230 controls the degree of vacuum. The chamber 210 is first made vacuous and the jig 100 is then made vacuous, thereby completing a process of creating a vacuum state. Before, after, or concurrently with the making the jig 100 and the chamber 210 vacuous, the temperature inside the jig 100 may be raised using the heating unit (180 of FIG. 7) included in the jig 100. As such, when the adhering object (400 of FIG. 11) and the to-be-adhered object (300 of FIG. 11) are adhered to each other, adhesion can be more easily performed and adhesion strength can be further increased. Here, the heating temperature of the heating unit 180 is 80° C. or below, preferably 25 to 35° C.

Subsequently, the vacuum state is cancelled from the chamber 210 leaving the to-be-adhered object and the adhering object adhered to each other in operation S4 of FIG. 10.

Referring to FIG. 13, if the interior of jig 100 is kept at the vacuum state by application of a vacuum to jig 100 via aperture 134 and if the vacuum state of the chamber (210 of FIG. 7) is cancelled, pressure is applied to upper and bottom surfaces of the jig 100. That is, the first and second flexible membranes 150 and 170 respectively formed on the first frame 110 and the second frame 160 of the jig 100 elongate into the jig 100 by pressure applied to the jig 100 from the chamber 210 Wherein the first frame 110 includes at least one aperture (not shown) to be covered by the second flexible membrane 170 as shown in the form of aperture 161 of the second frame 160. As a result, the actuator 140 disposed above the first flexible membrane 150 of the first frame 110 moves to the to-be-adhered object 300, e.g., a liquid crystal panel assembly, mounted on the seating pockets 122 along the guide 144 by a force which causes the first flexible membrane 150 to elongate into the jig 100. This means that the adhering object 400 disposed on the shock-absorbing member 190 on the top surface of the actuator 140, for example, the transparent film (410 of FIG. 9) having an adhesive layer (420 of FIG. 9) on its one side moves to the liquid crystal panel assembly 300.

The second flexible membrane 170 of the second frame 160 is used to prevent the liquid crystal panel assembly 300 from being deviated from the seating pockets 122 while the liquid crystal panel assembly 300 mounted on the seating pockets 122 is moved in an upward direction, the actuator 140 moves to the lower pocket 122b of the seating pockets 122 and the transparent film 410 having the adhesive layer 420 contacts the liquid crystal panel assembly 300.

At this time, pressure applied to the first and second flexible membranes 170 should be enough large to make the adhering object 400 close to the to-be-adhered object 300 and may be 0.1-3 kgf/cm², for example. The liquid crystal panel assembly 300 is adhered to the transparent film 410 by interposing the adhesive layer 420 using the pressure. At this time, opposing sides of the liquid crystal panel assembly 300 and the transparent film 410 are substantially completely adhered to each other almost at the same time, which means achieving perfect surface adhesion. That is, pressure applied to each of the first and second flexible membranes 150 and 170 uniformly distribute throughout the entire area of the first and second flexible membranes 150 and 170, pressure transmitted to each of the liquid crystal panel assembly 300 and the transparent film 410 having the adhesive layer 420 through the first and second flexible membranes 150 and 170 is not transmitted to a specific portion by the shock-absorbing member 190 placed between the actuator 140 and the adhering object 400 but is uniformly distributed, flatness is improved when the liquid crystal panel assembly 30 and the transparent film 410 having the adhesive layer 420 are adhered to each other and thereby surface adhesion is performed. Thus, since the liquid crystal panel assembly 300 and the transparent film 410 having the adhesive layer 420 are adhered to each other without a time difference, adhesion is performed without generation of bubbles. After the liquid crystal panel assembly 300 and the transparent film 410 having the adhesive layer 420 are adhered to each other, the adhesion state is maintained for about 2 seconds.

Subsequently, after the pressure of the jig 100 is removed and then, the switch 240 is opened, the jig 100 is moved out of the chamber 210 and then the second frame 160 is separated from the first frame 110 and thereafter removed the liquid crystal panel assembly 300 to which the transparent film 410 is attached is separated.

While the present invention has been described with regard to a bidirectional liquid crystal panel assembly as a to-be-adhered object by way of example, the described example is for illustration only and a transparent film can be adhered to a unidirectional liquid crystal panel assembly using a jig for surface adhesion according to an embodiment of the invention. In addition, while the present invention has been described with regard to a flexible transparent film made of a polymer resin and having an adhering object by way of example, the described example is for illustration only and a non-flexible transparent film can be adhered to a liquid crystal panel assembly using a jig for surface adhesion according to an embodiment of the invention as long as it perfect surface adhesion is performed, that is, adhesion is performed on opposing sides of an adhering object and a to-be-adhered object substantially concurrently without a time difference. Further, while the present invention has been described that a transparent film is adhered to a liquid crystal panel assembly using a jig for surface adhesion according to an embodiment of the invention, the invention is not limited thereto. The invention can also be used for adhesion between thermoplastic or thermocurable resin films, or between polymer resin film and a base member, for example, a wood panel, a metal panel, or a sheet made of an organic material, an inorganic material or a composite material of organic and inorganic materials.

As described above, when the adhering object and the to-be-adhered object are adhered to each other using the jig according to the present invention, pressure is uniformly applied to the adhering object and the to-be-adhered object and adhesion there between is concurrently performed without a time difference such that generation of bubbles is suppressed. In addition, even when the adhering object and the to-be-adhered object are made of e.g., glass, surface adhesion can be performed without causing damages to the adhering object and the to-be-adhered object, thereby improving processing efficiency.

While the present invention has been particularly shown and described with reference to exemplary embodiments thereof, it will be understood by those skilled in the art that various changes in form and details may be made therein without departing from the spirit and scope of the invention as defined by the following claims and equivalents thereof.

What is claimed is:

1. A jig comprising:
a first frame comprising a plurality of seating pockets, a plurality of actuators, each actuator having an associated seating pocket, and a first flexible membrane positioned below the actuators; and
a second frame adapted to cooperate with the first frame, the second frame including a second flexible membrane.

2. The jig according to claim 1, wherein each of the seating pockets has a first portion having a first circumference and second portion having a second, different circumference.

3. The jig according to claim 1, wherein the first and second flexible membranes are comprised of silicone-based rubber.

4. The jig according to claim 1, further comprising a shock-absorbing member positioned on a surface of each of the actuators.

5. The jig according to claim 4, wherein the shock-absorbing member is comprised of an elastic material.

6. The jig according to claim 1, wherein the actuators are movably attached to the first frame.

7. The jig according to claim 1, further comprising a heating unit associated with the at least one of the first and second frames.

8. The jig according to claim 7, wherein the heating unit is a hot plate.

9. A vacuum operative adhesion system comprising:
a jig including a first frame comprising a plurality of seating pockets, a plurality of actuators, each actuator having an associated seating pocket, and a first flexible membrane positioned below the actuators and a second frame adapted to cooperate with the first frame, the second frame including a second flexible membrane;
a chamber receiving the jig; and
a vacuum unit connected to the jig and the chamber.

10. The system of claim 9, wherein each of the seating pockets has a first portion having a first circumference and second portion having a second, different circumference.

11. The system of claim 9, wherein the first and second flexible membranes are comprised of silicone-based rubber.

12. The system of claim 9, further comprising a shock-absorbing member positioned on a surface of each of the actuators.

13. The system of claim 12, wherein the shock-absorbing member is comprised of an elastic material.

14. The system of claim 9, wherein the actuators are movably attached to the first frame.

15. The system of claim 9, further comprising a heating unit associated with the at least one of the first and second frames.

16. The system of claim 15, wherein the heating unit is a hot plate.

17. An adhesion method for adhering an adhering object to a to-be-adhered object, the method comprising:
placing the adhering object and the to-be-adhered object on an actuator and a seating pocket, respectively, of a jig;
moving a second frame of the jig into contact with a first frame of the jig;
placing the jig in a chamber;
evacuating the jig and the chamber, respectively; and
releasing a vacuum of the chamber.

18. The adhesion method of claim 17, further comprising mounting a shock-absorbing member on the actuator before the placing of the adhering object on the actuator.

19. The adhesion method of claim 18, wherein the shock-absorbing member is comprised of an elastic material.

20. The adhesion method of claim 17, further comprising applying a pressure to the chamber after releasing a vacuum of the chamber.

21. The adhesion method of claim 17, wherein in the performing of the surface adhesion, a degree of pressurization of the first and second flexible membranes is in a range of about 0.1 to about 3 kgf/cm².

22. The adhesion method of claim 17, further comprising heating the jig before the making of the jig and the chamber vacuous.

23. The adhesion method of claim 22, wherein the heating of the jig is performed using the heating unit disposed below the first frame.

24. The adhesion method of claim 22, wherein the heating temperature is not greater than 80° C.

25. The adhesion method of claim 17, wherein each of the seating pockets has a first portion having a first circumference and second portion having a second, different circumference.

26. The adhesion method of claim 17, wherein the second object is a liquid crystal display panel assembly.

27. The adhesion method of claim 17, wherein the liquid crystal display panel assembly includes a stopper and the stopper is positioned on a ledge of a of the seating pocket.

28. The adhesion method of claim 17, wherein the adhering object is a transparent film having an adhesive layer formed on one side.

29. The adhesion method of claim 28, wherein the adhesive layer is comprised of silicon or acrylic resin having a transmittance of 60% or more.
